(19) United States
(12) Patent Application Publication
(10) Pub. No.: US 2021/0364814 A1
(43) Pub. Date: Nov. 25, 2021

(54) INTEGRATED IMAGING DISPLAY DEVICE

(71) Applicant: BOE TECHNOLOGY GROUP CO., LTD., Beijing (CN)

(72) Inventors: Baoqiang WEI, Beijing (CN); Xiaochuan CHEN, Beijing (CN); Wenqing ZHAO, Beijing (CN); Chen Yu CHEN, Beijing (CN); Xiaochen NIU, Beijing (CN)

(21) Appl. No.: 16/610,301

(22) PCT Filed: May 9, 2019
(86) PCT No.: PCT/CN2019/086245

§ 371 Date: Nov. 1, 2019

(30) Foreign Application Priority Data
May 21, 2018 (CN) 201810491183.X

(51) Int. Cl. G02B 30/10; G02F 1/1335; G02F 1/13363; H01L 51/52

(52) U.S. Cl. CPC G02B 30/10; G02F 1/133526; G02F 1/1347; H01L 51/5275; G02F 1/13363

(57) ABSTRACT

An integrated imaging display device, including: a display component, and a micro-lens array and a low-pass filter disposed on a light-emitting side of the display component. The display component includes a plurality of display units; and the micro-lens array includes a plurality of micro-lenses corresponding to the plurality of display units.

The application claims priority to the Chinese patent application No. 201810491183.X, filed on May 21, 2018, the disclosure of which is incorporated herein by reference as part of the application.

### TECHNICAL FIELD

The present disclosure relates to an integrated imaging display device.

### BACKGROUND

Since integrated imaging has many advantages such as the capability of displaying real-time three-dimensional (3D) images with full true color and full parallax and has become a research hotspot in the field of naked eye 3D display. The basic principle is to use a micro-lens array to record the spatial field onto a film behind the micro-lens array. Each micro-lens corresponds to an image element on the film, and each image element records a part of information in the spatial scene. An image element array that is formed by the integration of all the image elements records the 3D information of the entire spatial scene. According to the reversibility of optical path, if the same micro-lens array in the case of recording is placed in front of the image element array, the original 3D spatial scene can be reconstructed in front of the micro-lens array.

### SUMMARY

At least one embodiment of the disclosure provides an integrated imaging display device, comprising: a display component, and a micro-lens array and a low-pass filter disposed on a light-emitting side of the display component, wherein the display component includes a plurality of display units; and the micro-lens array includes a plurality of micro-lenses corresponding to the plurality of display units.

In some examples, the plurality of display units are configured to display three-dimensional (3D) image information at different angles; and the micro-lens array is configured to synthesize the 3D image information displayed by the display units into a 3D image.

In some examples, the low-pass filter is configured to filter a Moiré fringe that a human eye can recognize.

In some examples, the low-pass filter includes: a crystal filter that allows light to be subjected to birefringence; the crystal filter is capable of filtering light with a frequency above a cut-off frequency; and the cut-off frequency is increased along with increase of a thickness of the crystal filter.

In some examples, the thickness of the crystal filter satisfies the following relationship:

$$d = T \frac{( {n}_{o}^{2} - {n}_{e}^{2} ) tan θ}{{n}_{o}^{2} {tan}^{2} θ + {n}_{e}^{2}} ,$$

wherein θ refers to an angle between incident light and an optical axis; nₒ refers to a refractive index of ordinary light; nₑ refers to a refractive index of extraordinary light; d refers to a separating distance between the ordinary light and the extraordinary light; and T refers to the thickness of the crystal filter.

In some examples, an angle between the optical axis of the crystal filter and a surface of the crystal filter is 45°.

In some examples, the crystal filter is made of a quartz crystal material.

In some examples, the low-pass filter includes one crystal filter; or the low-pass filter includes at least two crystal filters, and the crystal filters have different thicknesses.

In some examples, the integrated imaging display device further comprises: a first lens disposed on a light-emitting side of the micro-lens array, wherein the first lens is configured to converge the light emitted from the micro-lens array; and the low-pass filter is disposed between the display component and the first lens.

In some examples, the low-pass filter is disposed between the display component and the micro-lens array; or the low-pass filter is disposed between the micro-lens array and the first lens.

In some examples, the low-pass filter includes at least two low-pass filters; and spatial frequencies of the Moiré fringe that can be filtered by the at least two low-pass filters are not exactly the same.

In some examples, the low-pass filter includes at least two low-pass filters; spatial frequencies of the Moiré fringe that can be filtered by the at least two low-pass filters are not exactly the same; and at least one of the at least two low-pass filters is disposed between the display component and the micro-lens array, and at least one of the at least two low-pass filters is disposed between the micro-lens array and the first lens.

In some examples, the display component includes: a backlight module and a plurality of stacked liquid crystal display panels disposed in a light-emitting direction of the backlight module; or the display component includes: a plurality of stacked organic electroluminescence display panels.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic diagram of Moiré fringe formed by periodical stacked structures in the embodiment of the present disclosure;

FIG. 2 is a first schematic structural view of an integrated imaging display device provided by the embodiment of the present disclosure;

FIG. 3a is a schematic diagram illustrating the imaging principle of a single display unit;

FIG. 3b is a schematic diagram illustrating the imaging principle of a display component;

FIG. 4 is a second schematic structural view of the integrated imaging display device provided by the embodiment of the present disclosure;

FIG. 5 is a schematic diagram illustrating the pulse attributes of Moiré fringe in 2D frequency in the embodiment of the present disclosure;

FIG. 6 is a schematic diagram illustrating the propagation direction after light passes through a crystal filter in the embodiment of the present disclosure;

FIG. 7 is a third schematic structural view of the integrated imaging display device provided by the embodiment of the present disclosure; and

FIG. 8 is a fourth schematic structural view of the integrated imaging display device provided by the embodiment of the present disclosure.

Reference numerals of the accompanying drawings: 11—display component; 11′—display unit; 111—backlight module; 112—liquid crystal display; 113—organic electroluminescent display; 12—micro-lens array; 121—micro-lens; 13—low-pass filter; 14—first lens.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

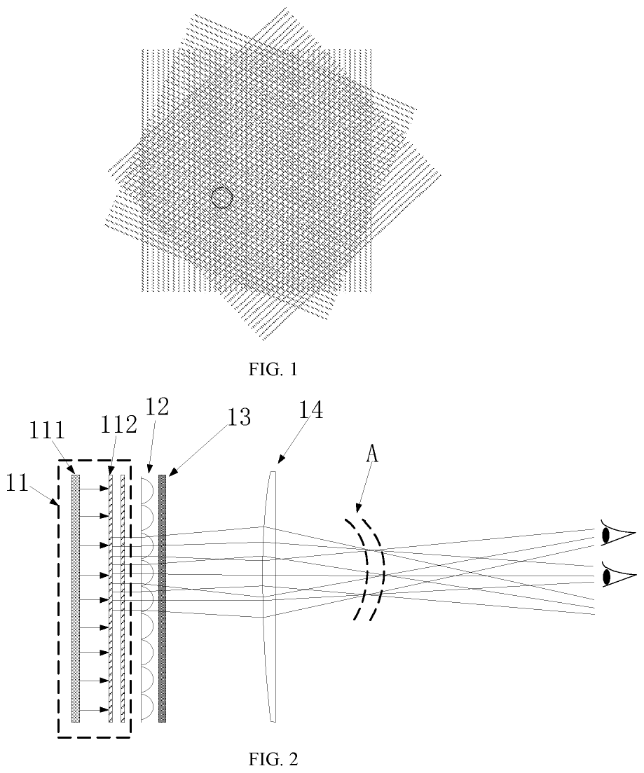

In integrated imaging display devices in some related arts, Moiré fringe can be easily generated due to the stacking phenomenon of periodical structures such as an array structure, a micro-lens array and a linear grating in a display component, for example, a structure encircled by a black circular frame in FIG. 1. Moiré fringe is a new structure, different from the original linear structure, formed by the stacking of periodic structures. The appearance of Moiré fringe will affect the image quality, resulting in poor three dimension (3D) effect of the integrated imaging display device.

The embodiment of the present disclosure provides an integrated imaging display device to solve the problem of poor 3D effect of the integrated imaging display device due to the appearance of Moiré fringe.

The specific embodiments of the integrated imaging display device provided by the embodiment of the present disclosure will be described in detail below with reference to the accompanying drawings. The thickness and the shape of film layers in the drawings do not reflect the true scale, and the purpose is only to illustrate the content of the present disclosure.

The embodiment of the present disclosure provides an integrated imaging display device, which, as shown in FIG. 2, comprises: a display component 11 and a micro-lens array 12 and a low-pass filter 13 disposed on a light-emitting side of the display component 11. The display component 11 includes a plurality of display units which are configured to display 3D image information at different angles. The micro-lens array 12 is configured to synthesize the 3D image information displayed by the display units into a 3D image. The low-pass filter 13 is configured to filter Moiré fringe that the human eye can recognize.

By arrangement of the low-pass filter capable of filtering the Moiré fringe that the human eye can recognize on the light-emitting side of the display component, the integrated imaging display device provided by the embodiment of the present disclosure can reduce or eliminate the Moiré fringe generated by the elements on the light incidence side of the low-pass filter and improve the 3D display effect of the integrated imaging display device.

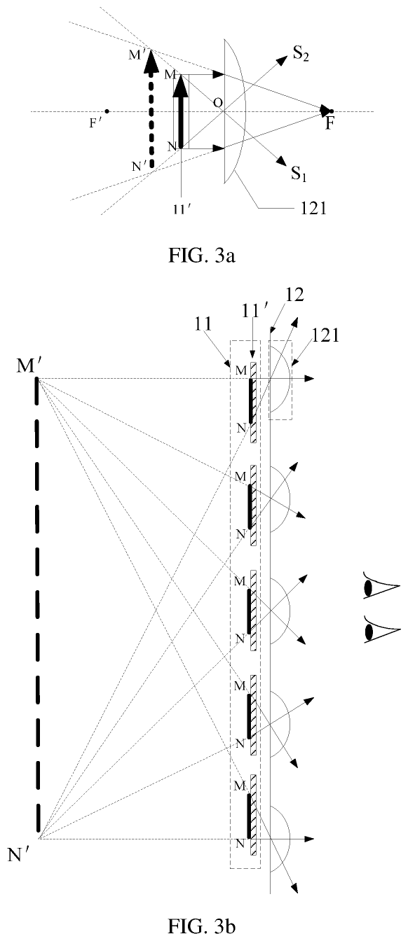

In some examples, the display component includes a plurality of display units which are configured to display 3D image information at different angles, and the plurality of display units can be arranged in an array. The micro-lens array includes: a plurality of micro-lenses in one-to-one correspondence with the plurality of display units. For instance, the micro-lenses are preferably convex lenses. For the convenience of production, plane convex lenses may be adopted. In the display process, the display units display the 3D image information at different angles, and the micro-lens array synthesizes the 3D image information displayed by the display units into a 3D image, so that the image viewed by the viewer can have three-dimension effect. For instance, as shown in FIG. 3a, as for one display unit 11′, as can be seen from the imaging principle of the convex lens, an image displayed by the display unit 11′ within the focal length of a micro-lens 121 is MN; a virtual image M′N′ is formed after light passes through the micro-lens 121; light which is perpendicularly incident into the micro-lens 121 beginning from the M point or the N point is incident into a focus F after passing through the micro-lens 121; and the propagation directions of light S₁ that passes through a central point O of an optical axis of the micro-lens 121 beginning from the M point and light S₂ that passes through the central point O of the optical axis of the micro-lens 121 beginning from the N point do not change. An optical path as shown in FIG. 3a can be obtained by drawing an optical path map. Therefore, the image that can be viewed by the viewer is the virtual image M′N′ formed by intersections of inverse extensions of refracted rays in the figure.

As shown in FIG. 3b, the display component 11 includes a plurality of display units 11′; the display units IF display 3D image information at different angles and display the same image MN; and the image displayed by the display units 11′ are imaged into the same virtual image M′N′ after passing through the micro-lens 121, that is, the images displayed by the display units 11′ are synthesized into the same 3D image after the imaging of the micro-lens array.

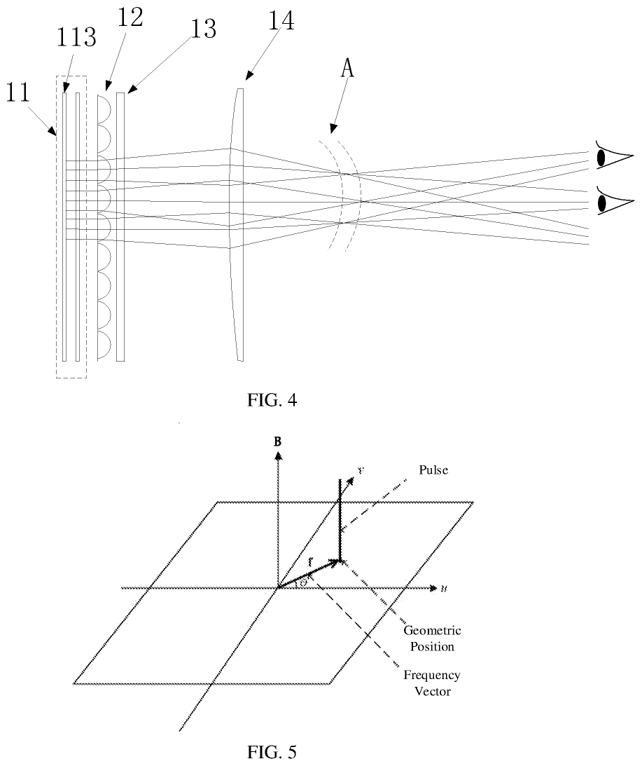

In some examples, in order to improve the three-dimension effect of the integrated imaging display device provided by the embodiment of the present disclosure, the display component may include two or more displays, for instance, may be arranged in the following mode: as shown in FIG. 2, the display component 11 may include: a backlight module 111 and a plurality of stacked liquid crystal display panels 112 disposed in the light-emitting direction of the backlight module 111; or as shown in FIG. 4, the display component 11 may include: a plurality of stacked organic electroluminescence display panels 113.

In the mode as shown in FIG. 2, the liquid crystal display panels 112 may share the backlight module 111, so as to simplify the structure of the display component. In the mode as shown in FIG. 4, as the organic electroluminescence display panels are active emitting elements and no backlight module is required to be arranged, the structure is simpler. By adoption of the above mode, the integrated imaging display device can realize 3D display more easily and have better 3D display effect.

Moiré fringe is a new structure that differs from the original linear structure and is formed by the stacking of periodic structures. Since there are many periodic structures in the display component, e.g., pixel structures arranged in an array, thin-film transistors (TFTs) arranged in an array, and a grid black matrix layer, a single-layer display will exhibit a certain degree of Moiré fringe. With the increase of the periodic structures, the Moiré fringe phenomenon will become more and more obvious, and even affect the 3D display effect of the integrated imaging display device. For example, a stacked structure composed of a single-layer display and a micro-lens array, a stacked structure composed of a multi-layer display, and a stacked structure composed of a multi-layer display and a micro-lens array will form relatively obvious Moiré fringe. In order to improve the 3D display effect, the display component in the integrated imaging display device is usually set as a multi-view single display or a multi-layer display, so that the integrated imaging display device is prone to form more obvious Moiré fringe.

The elimination principle of Moiré fringe will be described below with reference to the accompanying drawings. In order to explain the elimination principle of Moiré fringe more briefly, each layer structure in the stacked structure of the Moiré fringe can be represented by a monochrome image, and the Moiré fringe includes reflection Moiré fringe formed by reflection and transmissive Moiré fringe formed by transmission. The embodiment takes the reflection Moiré fringe as an example. These monochrome images may be represented by reflective functions. That is to say, as for any point (x, y) in the layer structure, the value 0 indicates that the reflection index of light is 0; the value 1 indicates that the reflection index of light is 1; and when the reflection index is higher, the grayscale value is higher. In addition, the transmissive Moiré fringe may be represented by transmissive function, and no further description will be given here. For instance, the Moiré fringe is formed by the stacking of m monochrome images, and the stacked image can be represented by the product of m reflective functions, for example, represented by the formula (1):

r(x,y)=r₁(x,y)r₂(x,y)⋅⋅⋅rₘ(x,y) (1)

According to the convolution theorem, the Fourier transform of the function product is the convolution of single function Fourier transform, then the Fourier transform of the formula (1) is the formula (2):

R(u,v)=R₁(u,v)**R₂(u,v)**⋅⋅⋅**Rₘ(u,v) (2)

Since the Moiré fringe is formed by the stacking of the periodic structures, the image with the periodic structure is continuous in the time domain, and corresponding frequency domain is discontinuous, that is, the spectrum of the graph contains pulses, for example, the spectrum of a linear grating of a one-dimensional periodic image is pulses with a comb structure. As shown in FIG. 5, each pulse in the two-dimensional spectrum includes three attributes, namely pulse index, frequency vector and amplitude. The geometric position of the frequency vector can be represented by a vector f, and the amplitude can be represented by B.

For instance, whether the pulse in the frequency domain corresponds to the Moiré fringe in the visible time domain depends on a human visual system, and the human eye cannot effectively distinguish details above a certain frequency, that is, the human visual system is equivalent to a low-pass filter. Some high-frequency parts in the spatial frequency of the Moiré fringe can be recognized by the human visual system. Therefore, in order to alleviate the influence of the Moiré fringe on the display effect, at least part of the Moiré fringe that can be recognized by the human eye needs to be removed.

In the embodiment of the present disclosure, the low-pass filter can filter light within a certain frequency range, and the frequency range has an intersection with the spatial frequency of the Moiré fringe that can be recognized by the human eye, so the low-pass filter can filter at least part of the Moiré fringe that the human eye can recognize. When the spatial frequency of the Moiré fringe that can be recognized by the human eye, generated by the elements on the incident side, is within the frequency range, the low-pass filter can filter all the Moiré fringe that can be recognized by the human eye. The specific numerical range of the spatial frequency of the Moiré fringe that can be recognized by the human eye needs to be determined according to factors such as the actual size of the display device, the application scenario, and the viewing position of the human eye. For example, as for a small-size mobile phone, as the size is small and the viewing distance of the human eye is relatively small, the spatial frequency of the Moiré fringe that can be recognized by the human eye, generated by the mobile phone, is relatively high. As for a large-size television or a large-screen display in a public place such as a shopping mall, as the size is large and the viewing distance of the human eye is relatively large, the spatial frequency of the Moiré fringe that can be recognized by the human eye is generally low. The frequency range of the light that can be filtered by the low-pass filter can be determined by changing the internal structure of the low-pass filter according to actual needs, so various types of Moiré fringe can be eliminated according to actual needs.

For instance, due to the stacking phenomenon of the periodic structures in the display component, Moiré fringe is prone to be formed on the light-emitting side of the display component, and the low-pass filter film can filter at least part of the Moiré fringe that can be recognized by the human eye. Thus, the low pass filter film can be disposed at any position of the light-emitting side of the display component. In the embodiment of the present disclosure, by adoption of the low-pass filter to directly filter the frequency component corresponding to the basic periodic structure of the Moiré fringe, the display device can be directly inhibited from forming Moiré fringe.

In the integrated imaging display device provided by the embodiment of the present disclosure, the low-pass filter may include: a crystal filter that allows light to be subjected to birefringence.

For instance, the crystal filter can filter light above the cut-off frequency, and the cut-off frequency is increased along with the increase of the thickness of the crystal filter.

That is to say, the crystal filter allows light of which the frequency is within the range of [0, f_{cut-off}] to pass through. As the cut-off frequency is increased along with the increase of the thickness of the crystal filter, when the thickness of the crystal filter is larger, the frequency range of the light passing through the crystal filter is larger, and the range of the light that can be filtered by the crystal filter is smaller. Therefore, the thickness of the crystal filter can be set according to actual needs to adjust the cut-off frequency of the crystal filter.

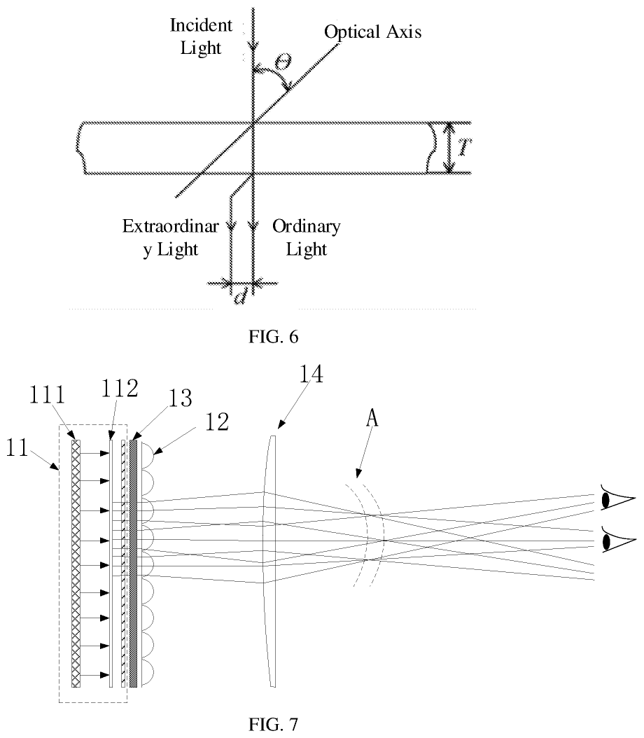

The low-pass filter belongs to an optical low-pass filter and can be made of a crystal filter with a certain thickness or stacked by at least two crystal filters. The number of the crystal filters is not limited herein. As shown in FIG. 6, after incident light carrying display information is incident into the crystal filter, birefringence occurs. Emergent light is divided into ordinary light (e beam) and extraordinary light (o beam); the separating distance between the ordinary light and the extraordinary light is d; and the distance d determines the cut-off frequency of the crystal filter. The energy of the high frequency portion exceeding the cut-off frequency will be greatly attenuated, so the crystal filter can filter high frequency Moiré fringe. By changing the target frequency of the difference frequency that will be formed by the incident beam, the purpose of weakening or eliminating Moiré fringe is achieved. In some examples, the spatial frequency of the Moiré fringe that can be perceived by the human eye can be calculated according to the pixel size and the total photosensitive area of the display component, and the number and the position of the crystal filters can be determined according to actual needs. By calculating the distance d between the ordinary light and the extraordinary light, the thickness of the crystal filter can be obtained, so as to obtain the low-pass filter capable of filtering Moiré fringe.

For instance, in the integrated imaging display device provided by the embodiment of the present disclosure, as shown in FIG. 6, the thickness T of the crystal filter is relevant to the separating distance d between the ordinary light and the extraordinary light, and the thickness of the crystal filter satisfies the following relationship:

$$d = T \frac{( {n}_{o}^{2} - {n}_{e}^{2} ) tan θ}{{n}_{o}^{2} {tan}^{2} θ + {n}_{e}^{2}} \qquad ( 3 )$$

wherein, θ refers to the angle between incident light and an optical axis; nₒ refers to the refractive index of the ordinary light; nₑ refers to the refractive index of the extraordinary light; d refers to the separating distance between the ordinary light and the extraordinary light; and T refers to the thickness of the crystal filter.

When tan θ=nₑ/nₒ, the maximum separating distance can be found. When nₑ≈nₒ and tan 45°=1, the formula (3) can be simplified as the formula (4):

$$d = T \frac{{n}_{o}^{2} - {n}_{e}^{2}}{{n}_{o}^{2} + {n}_{e}^{2}} \qquad ( 4 )$$

that is to say, when θ=45°, namely when the angle between the optical axis of the crystal filter and the surface of the crystal filter is 45°, the separating distance d between the ordinary light and the extraordinary light is maximum, and the maximum of d can be obtained from the formula (4).

In some examples, in the integrated imaging display device provided by the embodiment of the present disclosure, as the angle between the optical axis of the crystal filter and the surface of the crystal filter is 45°, namely θ=45°, the separating distance d between the ordinary light and the extraordinary light may be maximized to satisfy the condition in which one-dimensional interference fringes are separated, so that the beam after passing through the crystal filter can be separated, thereby causing a small change in the spatial frequency of the beam.

For instance, in the integrated imaging display device provided by the embodiment of the present disclosure, the crystal filter is made from quartz crystal materials. In addition, other materials with birefringence function may also be adopted. No limitation will be given here to the material of the crystal filter.

In some examples, in the integrated imaging display device provided by the embodiment of the present disclosure, the low-pass filter includes one crystal filter; or the low-pass filter includes at least two crystal filters, and the thicknesses of the crystal filters are different.

When the low-pass filter only includes one crystal filter, after determining the spatial frequency range of the Moiré fringe that can be recognized by the human eye, generated on the light incident side of the low-pass filter, the cut-off frequency of the crystal filter can be calculated according to the frequency range, and the cut-off frequency and the thickness of the crystal filter are in direct proportion. The thickness of the crystal filter can be obtained according to the formula (3), so that the separating distance between the ordinary light and the extraordinary light can satisfy the distance for separating the one-dimensional interference fringes, and then the beam with the same image information is divided into ordinary light and extraordinary light. Thus, a relatively staggered image is formed to cause a small change in the frequency of the beam to weaken the Moiré fringe phenomenon.

When the low-pass filter includes two or more than two crystal filters, after determining the spatial frequency range of the Moiré fringe that can be recognized by the human eye, generated on the light incident side of the low-pass filter, the thicknesses of the crystal filters in the low-pass filter can be set to be different from each other, so the cut-off frequencies of the crystal filters are different, and then the crystal filters can filter the Moiré fringe in different frequency ranges, thereby improving the effect of the low-pass filter in filtering the Moiré fringe. When the union of the spatial frequencies of the Moiré fringe that can be filtered by the crystal filters is greater than or equal to the spatial frequency range of the Moiré fringe generated on the light incident side of the low-pass filter, the low-pass filter can filter all the Moiré fringe generated on the incident side to achieve the purpose of completely eliminating Moiré fringe.

Moreover, as shown in FIG. 2, the integrated imaging display device provided by the embodiment of the present disclosure may further comprise: a first lens 14 disposed on a light-emitting side of the micro-lens array 12. The first lens 14 is configured to converge light emitted from the micro-lens array 12. The low-pass filter 13 is, for instance, disposed between the display component 11 and the first lens 14.

With reference to FIG. 3b simultaneously, in the case where the first lens is not arranged, the image displayed by the display component is imaged on the light incident side of the display component, and the viewer sees a virtual image on a rear surface of the display component. By adoption of the first lens 14 to converge the light emitted from the micro-lens array, the image displayed by the display component forms a real image at A in the figure, which reduces the distance between the viewer and the image displayed by the display component, so that the viewer can view the display image more clearly. In some examples, the first lens 14 is a large-diameter lens that better converges light.

For instance, the low-pass filter 13 is not disposed on the light-emitting side of the first lens 14, with the reason that: the image displayed by the display component 11 is imaged on a light-emitting side of the first lens 14, if the low-pass filter 13 is disposed on the first lens 14 to remove light of partial frequencies, the imaging quality may be affected, and then the display effect of the display device may be affected.

For instance, in the integrated imaging display device provided by the embodiment of the present disclosure, the low-pass filter may be set by the following modes.

Arrangement mode 1: the number of the low-pass filter is one.

As shown in FIG. 7, the low-pass filter 13 is disposed between the display component 11 and the micro-lens array 12. Thus, the low-pass filter 13 can reduce or eliminate the Moiré fringe formed by the stacking of the periodical structures of the display component 11. In addition, as the low-pass filter 13 reduces the Moiré fringe formed by the display component 11, after the light runs through the micro-lens array 12 again, the Moiré fringe will not be easily generated, so the influence of the Moiré fringe on the display effect can be eliminated.

Or as shown in FIG. 2, the low-pass filter 13 is disposed between the micro-lens array 12 and the first lens 14. Thus, the low-pass filter 13 can reduce or eliminate the Moiré fringe formed by the stacking of the periodical structures of the display component 11 and the micro-lens array 12, so as to reduce or eliminate the influence of the Moiré fringe on the display effect.

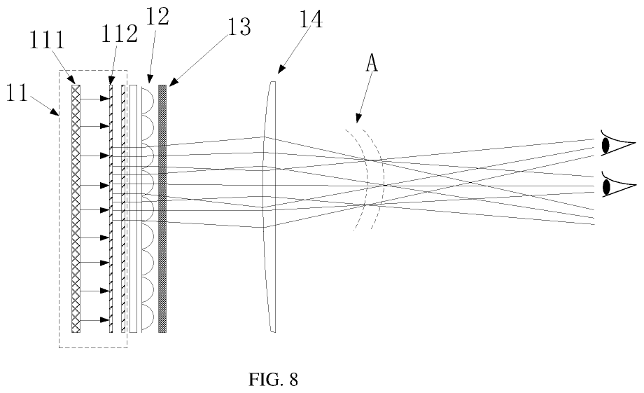

Arrangement mode 2: the number of the low-pass filters is two, and the spatial frequencies of the Moiré fringe that can be filtered by the low-pass filters are not exactly the same. For instance, (1) both the low-pass filters are disposed between the display component and the micro-lens array; or (2) both the low-pass filters are disposed between the micro-lens array and the first lens; or (3) as shown in FIG. 8, at least one low-pass filter is respectively disposed between the display component and the micro-lens array and between the micro-lens array and the first lens.

When the number of the low-pass filters is two or more, the spatial frequency of the Moiré fringe that can be filtered by the low-pass filters are not exactly the same, so as to improve the capability of filtering the Moiré fringe, thereby further improving the 3D display effect of the display device.

In addition, as there is Moiré fringe in any periodical stacking structure, in order to fully eliminate the influence of Moiré fringe, the low-pass filter can be disposed at a light-emitting position of all the periodical structures, and the position and the number of the low-pass filters can be set according to actual needs. No limitation will be given here.

By arrangement of the low-pass filter that can filter the Moiré fringe on the light-emitting side of the display component, the integrated imaging display device provided by the embodiment of the present disclosure can reduce or eliminate the Moiré fringe that can be recognized by the human eye, generated on the light incident side of the low-pass filter, and improve the 3D display effect of the integrated imaging display device.

The foregoing is merely exemplary embodiments of the invention, but is not used to limit the protection scope of the invention. The protection scope of the invention shall be defined by the attached claims.

1. An integrated imaging display device, comprising: a display component, and a micro-lens array and a low-pass filter disposed on a light-emitting side of the display component, wherein
the display component includes a plurality of display units; and
the micro-lens array includes a plurality of micro-lenses corresponding to the plurality of display units.

2. The integrated imaging display device according to claim 1, wherein the plurality of display units are configured to display three-dimensional (3D) image information at different angles; and the micro-lens array is configured to synthesize the 3D image information displayed by the display units into a 3D image.

3. The integrated imaging display device according to claim 1, wherein the low-pass filter is configured to filter a Moiré fringe that a human eye can recognize.

4. The integrated imaging display device according to claim 1, wherein the low-pass filter includes: a crystal filter that allows light to be subjected to birefringence;
the crystal filter is capable of filtering light with a frequency above a cut-off frequency; and the cut-off frequency is increased along with increase of a thickness of the crystal filter.

5. The integrated imaging display device according to claim 4, wherein the thickness of the crystal filter satisfies the following relationship:
$$d = T \frac{( {n}_{o}^{2} - {n}_{e}^{2} ) tan θ}{{n}_{o}^{2} {tan}^{2} θ + {n}_{e}^{2}}$$
wherein θ refers to an angle between incident light and an optical axis; nₒ refers to a refractive index of ordinary light; nₑ refers to a refractive index of extraordinary light; d refers to a separating distance between the ordinary light and the extraordinary light; and T refers to the thickness of the crystal filter.

6. The integrated imaging display device according to claim 5, wherein an angle between the optical axis of the crystal filter and a surface of the crystal filter is 45°.

7. The integrated imaging display device according to claim 4, wherein the crystal filter is made of a quartz crystal material.

8. The integrated imaging display device according to claim 4, wherein the low-pass filter includes one crystal filter; or
the low-pass filter includes at least two crystal filters, and the crystal filters have different thicknesses.

9. The integrated imaging display device according to claim 1, further comprising: a first lens disposed on a light-emitting side of the micro-lens array, wherein the first lens is configured to converge the light emitted from the micro-lens array; and
the low-pass filter is disposed between the display component and the first lens.

10. The integrated imaging display device according to claim 9, wherein the low-pass filter is disposed between the display component and the micro-lens array; or
the low-pass filter is disposed between the micro-lens array and the first lens.

11. The integrated imaging display device according to claim 10, wherein the low-pass filter includes at least two low-pass filters; and spatial frequencies of the Moiré fringe that can be filtered by the at least two low-pass filters are not exactly the same.

12. The integrated imaging display device according to claim 9, wherein the low-pass filter includes at least two low-pass filters; spatial frequencies of the Moiré fringe that can be filtered by the at least two low-pass filters are not exactly the same; and
at least one of the at least two low-pass filters is disposed between the display component and the micro-lens array, and at least one of the at least two low-pass filters is disposed between the micro-lens array and the first lens.

13. The integrated imaging display device according to claim 1, wherein the display component includes: a backlight module and a plurality of stacked liquid crystal display panels disposed in a light-emitting direction of the backlight module; or
the display component includes: a plurality of stacked organic electroluminescence display panels.

14. The integrated imaging display device according to claim 1, wherein the low-pass filter is disposed between the display component and the micro-lens array; or
the low-pass filter is disposed at a side of the micro-lens array away from the display component.

15. The integrated imaging display device according to claim 3, wherein the low-pass filter includes at least two low-pass filters; spatial frequencies of the Moiré fringe that can be filtered by the at least two low-pass filters are not exactly the same; and
at least one of the at least two low-pass filters is disposed between the display component and the micro-lens array, and at least one of the at least two low-pass filters is disposed at a side of the micro-lens array away from the display component.
